(19) United States
(12) Patent Application Publication
(10) Pub. No.: US 2013/0198587 A1
(43) Pub. Date: Aug. 1, 2013

(54) MEMORY BUFFER PERFORMING ERROR CORRECTION CODING (ECC)

(71) Applicants: JEONG-KYOUM KIM, SEOUL (KR); JUNG HWAN CHOI, HWASEONG-SI (KR); SEOK HUN HYUN, SEONGNAM-SI (KR); SEONG JIN JANG, SEONGNAM-SI (KR)

(72) Inventors: JEONG-KYOUM KIM, SEOUL (KR); JUNG HWAN CHOI, HWASEONG-SI (KR); SEOK HUN HYUN, SEONGNAM-SI (KR); SEONG JIN JANG, SEONGNAM-SI (KR)

(73) Assignee: SAMSUNG ELECTRONICS CO., LTD., SUWON-SI (KR)

(21) Appl. No.: 13/611,566

(22) Filed: Sep. 12, 2012

(30) Foreign Application Priority Data
Jan. 26, 2012 (KR) 10-2012-0007981

(51) Int. Cl. H03M 13/05; G06F 11/10

(52) U.S. Cl. 714/763; 714/E11.034

(57) ABSTRACT

A memory system includes a semiconductor memory device, a memory controller for controlling the semiconductor memory device, and a memory buffer connected between the semiconductor memory device and the memory controller. The memory buffer is configured to perform error correction coding (ECC) on first data that is received from the memory controller to be stored in the semiconductor memory device and to perform ECC on second data read from the semiconductor memory device.

### CROSS-REFERENCE TO RELATED APPLICATIONS

A claim of priority under 35 U.S.C. §119 is made to Korean Patent Application No. 10-2012-0007981, filed on Jan. 26, 2012, in the Korean Intellectual Property Office, the entire contents of which are hereby incorporated by reference.

### BACKGROUND

Embodiments of the inventive concept relate to memory buffers, and more particularly, to memory buffers improving error detecting and correcting capabilities, devices including the memory buffers, and methods of performing the improved error detecting and correcting capabilities.

In general, a memory module that includes a memory buffer and a memory device does not perform error detection and correction. Rather, a memory controller that controls the memory module performs error detection and correction. Thus, the memory buffer included in the memory module is used only to buffer and transmit data between the memory controller and the memory device.

In other words, during data transmission, the memory buffer does not detect or correct errors that may occur when data is transmitted from the memory controller to the memory buffer or when data is transmitted from the memory device to the memory buffer. Thus, there is a need for enabling a memory buffer to detect and correct errors in data input to the memory buffer.

### SUMMARY

According to an aspect of the inventive concept, there is provided a memory system including a semiconductor memory device, a memory controller for controlling the semiconductor memory device, and a memory buffer connected between the semiconductor memory device and the memory controller. The memory buffer is configured to perform error correction coding (ECC) on first data that is received from the memory controller to be stored in the semiconductor memory device and to perform ECC on second data read from the semiconductor memory device.

The memory buffer may include an ECC block having at least two ECC algorithms. The ECC block is configured to perform ECC according to an ECC algorithm selected from among the at least two ECC algorithms.

According to another aspect of the inventive concept, there is provided a semiconductor device including an ECC logic circuit having multiple different ECC algorithms and an ECC algorithm selector for selecting an ECC algorithm from among the different ECC algorithms. The ECC logic circuit is configured to generate ECC data using the ECC algorithm selected by the ECC algorithm selector.

The semiconductor device may further include first and second selectors. The first selector is configured to transmit first data received from outside to the ECC logic circuit and to transmit first ECC data received from the ECC logic circuit to the outside, in response to a command signal. The second selector is configured to transmit second ECC data received from the ECC logic circuit to a semiconductor memory device and to transmit second data received from the semiconductor memory device to the ECC logic circuit, in response to the command signal. The ECC logic circuit may generate the first ECC data by performing ECC on the second data, and generate the second ECC data by performing ECC on the first data.

The ECC logic circuit may further include multiple ECC units for performing the multiple different ECC algorithms, respectively, the first ECC data and the second ECC data being respectively generated from the second data and the first data using an ECC unit selected from among the multiple ECC units. One of the ECC units may be selected by the ECC algorithm selector when the semiconductor device is initialized or when a built-in self test (BIST) is performed.

Each of the ECC units may include an ECC decoder, a determination unit, an ECC buffer, and a third selector. The ECC decoder may determine whether an error is detected from the second data or the first data, based on an ECC algorithm corresponding to the selected ECC unit. The determination unit may determine whether a number of bits of a detected error is equal to a predetermined number of bits and output a control signal based on a result of the determination, when the error is detected from the first data or the second data. The ECC corrector may generate the first ECC data from the second data or generate the second ECC data from the first data according to the corresponding ECC algorithm, based on the control signal, when the number of bits of the detected error is equal to the predetermined number of bits. The third selector may output the first ECC data and the second ECC data or output the first data and the second data, based on the control signal.

The ECC decoder and the ECC corrector included in each of the ECC units may be embodied according to different logics, based on the corresponding ECC algorithm.

The ECC logic circuit may further include first and second selection units. The first selection unit may select a path for the received second data and first data, in response to the command signal, and the second selection unit may select a path for the first ECC data and the second ECC data generated by the selected ECC unit, in response to the command signal.

The semiconductor device may further include first and second buffer units. The first buffer unit may buffer the first data received from the outside, output the buffered first data to the first selector, buffer the first ECC data received from the first selector, and output the buffered first ECC data to the outside. The second buffer unit may buffer the second data received from the semiconductor memory device, output the buffered second data to the second selector, buffer the second ECC data received from the second selector, and output the buffered second ECC data to the semiconductor memory device.

The semiconductor device may be a memory buffer may be connected between a semiconductor memory device and a memory controller that controls the semiconductor memory device, and may be configured to perform ECC on data exchanged between the semiconductor memory device and the memory controller.

The semiconductor device may be a memory controller for transmitting the ECC data to a semiconductor memory device, and controlling an operation of the semiconductor memory device.

A memory module may include the semiconductor device and a semiconductor memory device for receiving the ECC data generated by the semiconductor device, and storing the ECC data. The semiconductor device of the memory module may further include first and second selectors. The first selector may be configured to transmit first data received from outside to the ECC logic circuit and to transmit first ECC data received from the ECC logic circuit to the outside, in response to a command signal. The second selector may be configured to transmit second ECC data received from the ECC logic circuit to the semiconductor memory device and to transmit second data received from the semiconductor memory device to the ECC logic circuit, in response to the command signal. The ECC logic circuit may generate the first ECC data by performing ECC on the second data, and generate the second ECC data by performing ECC on the first data. Also, a memory system may include the memory module and a memory controller configured to control operations of the semiconductor memory device installed in the memory module via the semiconductor device.

According to another aspect of the inventive concept, there is provided a method of data processing by a memory buffer in a memory system. The method includes selecting an ECC unit from multiple ECC units for performing error detection on write data or read data received by the memory buffer and for outputting corresponding ECC information. The multiple ECC units are configured to perform corresponding different ECC algorithms, respectively. The method further includes determining whether an error is detected in the received write data or read data based on the ECC information, outputting the write data or the read data when it is determined that no error is detected, and generating and outputting ECC data for the write data or the read data, based on the ECC algorithm corresponding to the selected ECC unit, when it is determined that an error is detected.

The method may further include determining whether the number of bits of the detected error is equal to a predetermined number of bits when it is determined that the error is detected, outputting the write data or the read data when it is determined that the number of bits is not equal to the predetermined number of bits, and generating and outputting ECC data for the write data or the read data, based on the ECC algorithm corresponding to the selected ECC unit when it is determined that the number of bits is equal to the predetermined number of bits.

The ECC algorithm performed by the selected ECC unit may correspond to a memory controller which provides the write data to or receives the read data from the memory buffer. Selecting the ECC unit may occur when the memory buffer is initialized or when a memory module containing the memory buffer performs a built-in self test (BIST).

The method may further include receiving a command signal from the memory controller indicating whether to receive the write data from the memory controller via a first path or to receive the read data from a semiconductor memory device via a second path.

### BRIEF DESCRIPTION OF THE DRAWINGS

Illustrative embodiments will be more clearly understood from the following detailed description taken in conjunction with the accompanying drawings, in which:

FIG. 1 is a schematic block diagram of a memory system, according to an embodiment of the inventive concept;

FIG. 2 is a schematic block diagram of a memory module, according to an embodiment of the inventive concept;

FIG. 3 is a schematic block diagram of an error correction coding (ECC) block illustrated in FIG. 2, according to an embodiment of the inventive concept;

FIG. 4 is a schematic block diagram of an ECC logic circuit illustrated in FIG. 3, according to an embodiment of the inventive concept;

FIG. 5 is a schematic block diagram of a representative ECC unit illustrated in FIG. 4, according to an embodiment of the inventive concept;

FIG. 6 is a block diagram illustrating a data path corresponding to a write operation of a semiconductor memory device, according to an embodiment of the inventive concept;

FIG. 7 is a block diagram illustrating a data path corresponding to a read operation of a semiconductor memory device, according to an embodiment of the inventive concept; and

FIG. 8 is a flowchart illustrating a data processing method performed by a memory system, according to an embodiment of the inventive concept.

### DETAILED DESCRIPTION OF THE EMBODIMENTS

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. In the drawings, the size and relative sizes of layers and regions may be exaggerated for clarity. Unless otherwise noted, like reference numerals denote like elements throughout the attached drawings and written description, and thus descriptions will not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc., may be used herein to describe various elements, these elements should not be limited by these terms. These terms are only used to distinguish one element from another. For example, a first signal could be termed a second signal, and similarly, a second signal could be termed a first signal, without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

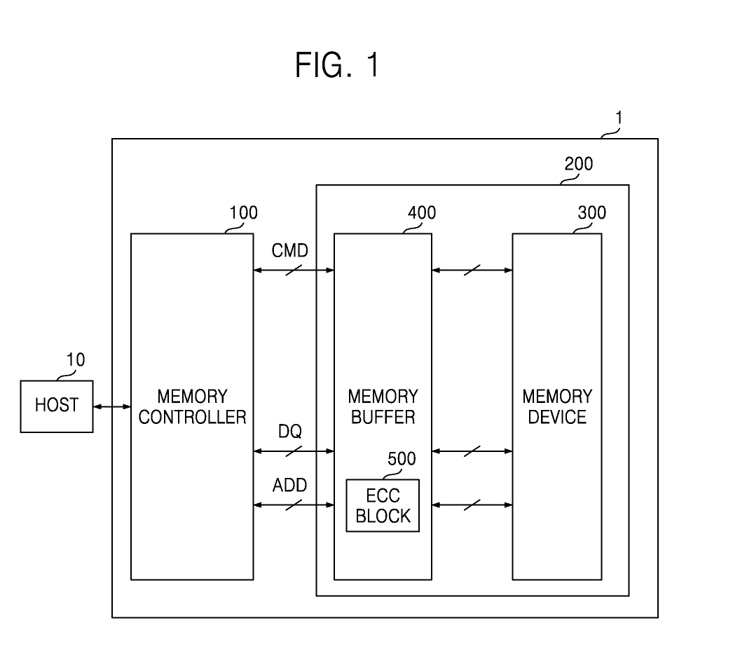

FIG. 1 is a schematic block diagram of a memory system, according to an embodiment of the inventive concept. Referring to FIG. 1, a memory system 1 includes a memory controller 100 and a memory module 200. The memory module 200 includes a memory buffer 400 and a semiconductor memory device 300.

The semiconductor memory device 300 may be a dynamic random access memory (DRAM), for example, including a memory cell array (not shown) in which multiple memory cells are arranged in rows and columns. However, other types of semiconductor memory devices and/or arrangements of memory cells may be included without departing from the scope of the present teachings.

A host 10 communicates with the memory system 1 using an interface protocol, such as Peripheral Component Interconnect-Express (PCI-E), Advanced Technology Attachment (ATA), Serial ATA (SATA), Parallel ATA (PATA), or Serial Attached Small computer system interface (SAS). However, other interface protocols may be used to enable communication between the host 10 and the memory system 1, such as universal serial bus (USB), Multi-Media Card (MMC), Enhanced Small Disk Interface (ESDI), Integrated Drive Electronics (IDE), and the like.

The memory controller 100 controls overall operations of the memory system 1, and controls exchange of data between the host 10 and the memory module 200. The memory controller 100 also transmits data to and receives data from the semiconductor memory device 300 via a data pin DQ in response to requests from the host 10. The memory controller 100 continuously supplies an address signal ADD together with a command CMD for an active operation of the semiconductor memory device 300, supplies an address signal ADD together with a command CMD for a write/read operation of the semiconductor memory device 300, and supplies an address signal ADD together with a command CMD for a refresh operation of the semiconductor memory device 300. In this case, the data, the command CMD, and the address signal ADD output from the memory controller 100 may be supplied to the semiconductor memory device 300 via the memory buffer 400.

The memory buffer 400 is connected between the memory controller 100 and the semiconductor memory device 300. The memory buffer 400 is configured to buffer data received from the memory controller 100 and to output the buffered data to the semiconductor memory device 300 via the data pin DQ, and to buffer data received from the semiconductor memory device 300 and to output the buffered data to the memory controller 100 via the data pin DQ. The memory buffer 400 includes an error correction coding (ECC) block 500. The ECC block 500 performs ECC on data (first data) that is output from the memory controller 100 to be stored in the semiconductor memory device 300, or on data (second data) read from the semiconductor memory device 300. Thus, the memory buffer 400 is able to perform ECC on data exchanged between the memory controller 100 and the semiconductor memory device 300. The memory buffer 400 is described in detail below.

The memory module 200, according to an embodiment, may be embodied as a Load Reduced (LR)-Dual In-line Memory Module (DIMM), for example. However, other types of memory modules may be incorporated without departing from the scope of the present teachings.

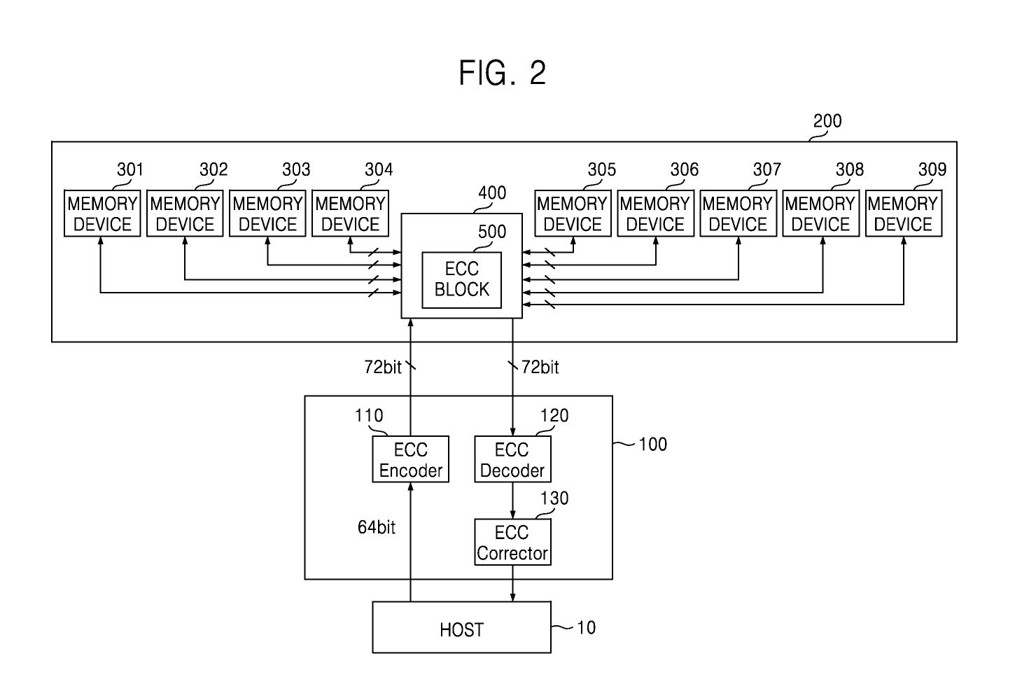

FIG. 2 is a schematic block diagram of a representative memory module, according to an embodiment of the inventive concept. Referring to FIG. 2, memory module 200 includes semiconductor memory devices 301 to 309 and memory buffer 400. The memory module 200 communicates with memory controller 100, which includes a first ECC encoder 110, a first ECC decoder 120, and a first ECC corrector 130.

The first ECC encoder 110 receives data from the host 10, generates parity bits for the received data, and outputs the data including the parity bits to the memory buffer 400. For example, when the data output from the host 10 is 64-bit data, the first ECC encoder 110 may output 72-bit data to the memory buffer 400, since eight parity bits are needed to correct a 1-bit error. For convenience of explanation, the current embodiment is described with respect to a case in which 64-bit data is received from the host 10, although the inventive concept is not limited to this implementation.

The memory buffer 400 receives data from the first ECC encoder 110, buffers the received data, and then outputs the buffered data to the semiconductor memory devices 301 to 309. Also, the memory buffer 400 receives data from the semiconductor memory devices 301 to 309, buffers the received data, and then outputs the buffered data to the first ECC decoder 120.

According to an embodiment, the memory buffer 400 further includes ECC block 500. The ECC block 500 may perform error detection using data received from the memory controller 100 and parity bits included in data received from the semiconductor memory devices 301 to 309. More particularly, the ECC block 500 receives data generated by the first ECC encoder 110, performs error detection and correction on the received data, and outputs the error-corrected data to the semiconductor memory devices 301 to 309. Also, the ECC block 500 receives data from the semiconductor memory devices 301 to 309, performs error detection and correction on the received data, and outputs the error-corrected data to the first ECC decoder 120.

The first ECC decoder 120 detects errors included in the data transmitted from the memory buffer 400 to the memory controller 100. The first ECC corrector 130 corrects the errors detected by the first ECC decoder 120, and outputs the error-corrected data to the host 10. FIG. 2 illustrates nine semiconductor memory devices 301 to 309 as an example for explaining a case in which the memory module 200 includes semiconductor memory devices that input and/or output 8-bit data. However, the number of semiconductor memory devices included in the memory module 200 may vary, without departing from the scope of the present teachings.

Accordingly, the ECC block 500 is able to detect and correct errors in data transmitted between the memory controller 100 and the memory buffer 400, as well as errors in data transmitted between the memory buffer 400 and each of the semiconductor memory devices 301 to 309.

Referring to FIG. 2, the ECC block 500 is included in the memory buffer 400, although the inventive concept is not limited to this configuration. For example, the ECC block 500 may be included in the memory controller 100 and/or the memory buffer 400. Likewise, the first ECC encoder 110, the first ECC decoder 120, and the first ECC corrector 130 are depicted in the memory controller 100, although the inventive concept is not limited to this configuration. For example, one or more of the first ECC encoder 110, the first ECC decoder 120, and the first ECC corrector 130 may be included in the host 10.

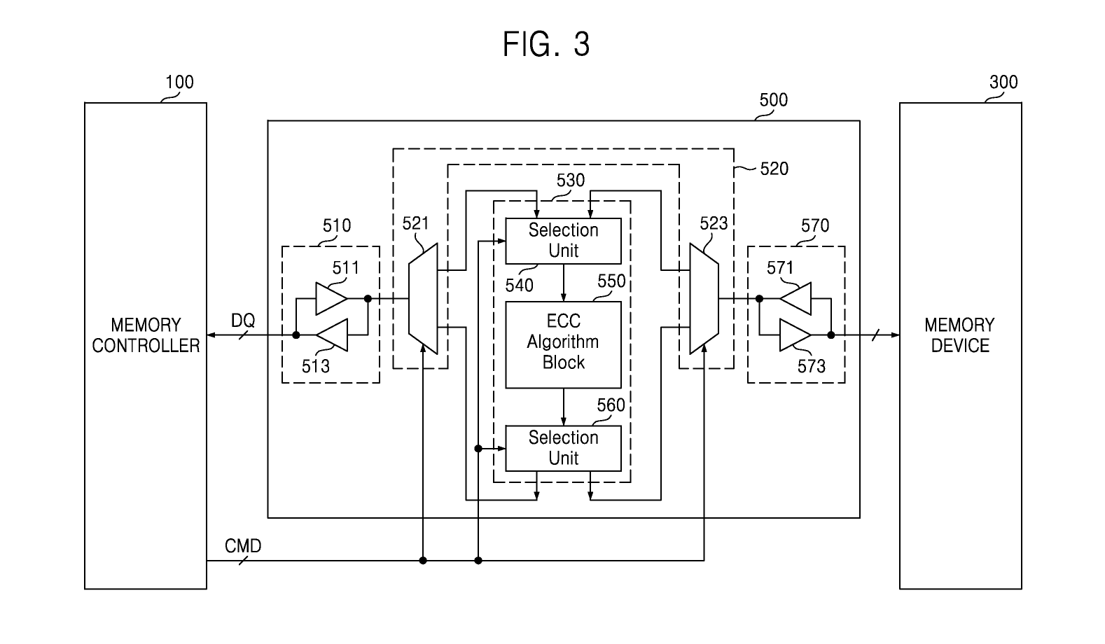

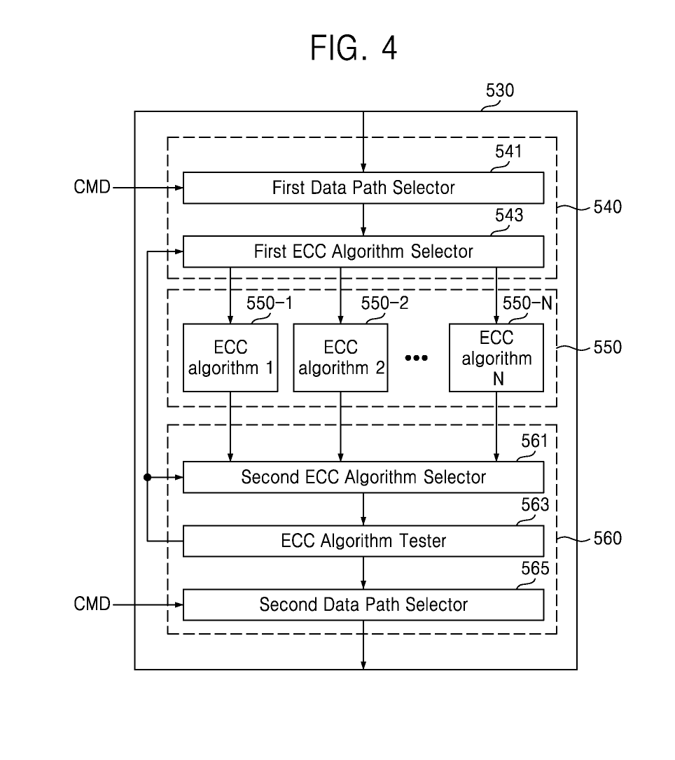

FIG. 3 is a schematic block diagram of the ECC block 500 illustrated in FIG. 2, according to an embodiment of the inventive concept. FIG. 4 is a schematic block diagram of an ECC logic circuit 530 illustrated in FIG. 3, according to an embodiment of the inventive concept.

Referring to FIG. 3, the ECC block 500 includes a first buffer unit 510, a selection circuit 520, an ECC logic circuit 530, and a second buffer unit 570. The first buffer unit 510 includes a first buffer gate 511 and a second buffer gate 513. The first buffer gate 511 buffers write data received from the host 10 of FIG. 1 via the memory controller 100, and outputs the buffered write data to a first selector 521 in the selection unit 520. The second buffer gate 513 buffers read data received from the first selector 521 and outputs the buffered read data to the memory controller 100. The second buffer unit 570 includes a third buffer gate 571 and a fourth buffer gate 573. The third buffer gate 571 buffers read data received from the semiconductor memory device 300, and outputs the buffered read data to a second selector 523 in the selection unit 520. The fourth buffer gate 573 buffers write data received from the second selector 523, and outputs the buffered write data to the semiconductor memory device 300.

In the depicted embodiment, the selection circuit 520 includes a multiplexer and a demultiplexer, indicated as the first selector 521 and the second selector 523. However, the selection circuit 520 is not limited to this configuration. The first selector 521 may transmit write data buffered by the first buffer unit 510 to the ECC logic circuit 530 or may transmit first ECC data received from the ECC logic circuit 530 to the first buffer unit 510, according to a command CMD received from the memory controller 100. The second selector 523 may transmit second ECC data received from the ECC logic circuit 530 to the semiconductor memory device 300 or may transmit read data received from the semiconductor memory device 300 to the ECC logic circuit 530, according to a command CMD received from the memory controller 100.

The ECC logic circuit 530 generates the first ECC data by performing ECC on read data received from the semiconductor memory device 300, and generates the second ECC data by performing ECC on write data received from the memory controller 100. An example of the ECC logic circuit 530 is illustrated in FIG. 4.

Referring to FIG. 4, the ECC logic circuit 530 includes a first selection unit 540, an ECC algorithm block 550, and a second selection unit 560. The first selection unit 540 includes a first data path selector 541 and a first ECC algorithm selector 543. The second selection unit 560 includes a second ECC algorithm selector 561, an ECC algorithm tester 563, and a second data path selector 565.

The first data path selector 541 outputs write data received from the memory controller 100 or read data received from the semiconductor memory device 300 to the first ECC algorithm selector 543 using a path selected based on a command CMD received from the memory controller 100. For example, the first data path selector 541 may output the write data (e.g., first data) received from the memory controller 100 via a first path, and may output the read data (e.g., second data) received from the semiconductor memory device 300 via a second path. The first ECC algorithm selector 543 may output the write data received via the first path or the read data received via the second path to an ECC unit selected, for example, under control of the ECC algorithm tester 563.

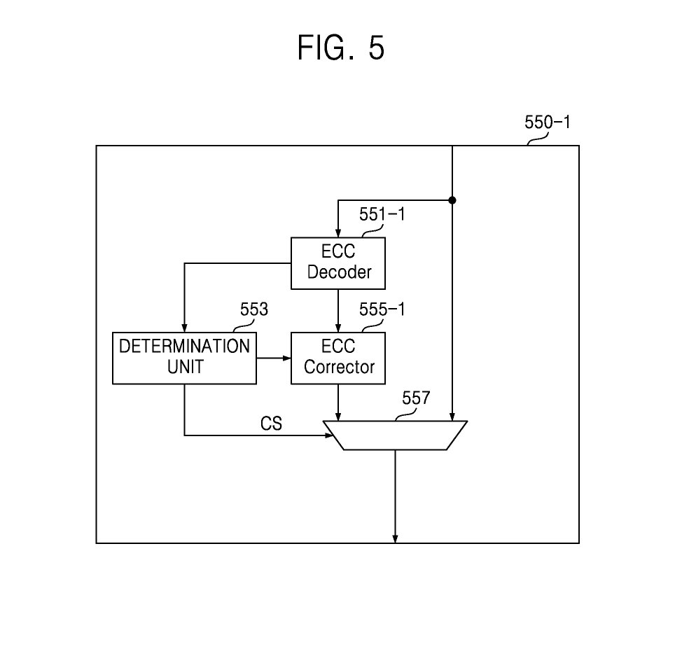

The ECC algorithm block 550 includes multiple ECC units 550-1 to 550-N for respectively performing ECC algorithms corresponding to multiple memory controllers (not shown). For example, a first ECC unit 550-1 may perform ECC algorithm 1, a second ECC unit 550-2 may perform ECC algorithm 2, and an Nth ECC unit 550-N may perform ECC algorithm N. An ECC unit selected from among the ECC units 550-1 to 550-N by the first ECC algorithm selector 543 performs ECC error detection on the write data or the read data to generate ECC data, and then outputs the generated ECC data, as will be described in detail with reference to FIG. 5 below.

The second ECC algorithm selector 561 receives ECC data from an ECC unit selected under control of the ECC algorithm tester 563, and then outputs the ECC data. The ECC algorithm tester 563 may select an ECC unit corresponding to the memory controller 100, for example, from among the ECC units 550-1 to 550-N when the memory module 200 performs a built-in self test (BIST) or when the memory buffer 400 is initialized. After the ECC unit corresponding to the memory controller 100 is selected, the ECC algorithm tester 563 may be disabled while the ECC logic circuit 530 performs ECC. For example, the ECC algorithm tester 563 may select an ECC unit having least error from among the multiple ECC units 550-1 to 550-N, based on results of sequentially inputting data received from the memory controller 100 or the semiconductor memory device 300 to the ECC units 550-1 to 550-N. However, methods of selecting an ECC unit corresponding to the memory controller 100 using the ECC algorithm tester 563 are not limited to this implementation.

The second data path selector 565 outputs ECC data received from the ECC logic circuit 550 to the first selector 521 or the second selector 523 via a path selected based on a command CMD received from the memory controller 100.

According to an embodiment of the inventive concept, the memory buffer 400 may include multiple ECC decoders and multiple ECC correctors according to ECC algorithms corresponding to multiple memory controllers, and may thus perform error detection and correction according to various ECC algorithms.

FIG. 5 is a schematic block diagram of a representative ECC unit (e.g., of ECC units 550-1 to 550-N) illustrated in FIG. 4, according to an embodiment of the inventive concept. For convenience of explanation, FIG. 5 will be described with reference to the first ECC unit 550-1 from among the ECC units 550-1 to 550-N, although the description may apply equally to any of the ECC units 550-1 to 550-N. An ECC decoder 551 and an ECC corrector 555 included in each of the ECC units 550-1 to 550-N incorporate different logic based on the corresponding ECC algorithm.

Referring to FIG. 5, the representative first ECC unit 550-1 includes a second ECC decoder 551-1, a determination unit 553, a second ECC corrector 555-1, and a third selector 557. The second ECC decoder 551-1 determines whether an error is detected from read data received from the semiconductor memory device 300 of FIG. 1 or write data received from the memory controller 100, based on an ECC algorithm corresponding to the memory controller 100 of FIG. 1.

When the second ECC decoder 551-1 determines that no error is detected from the write data or the read data, then the determination unit 553 outputs a control signal CS indicating this fact to the third selector 557. When the second ECC decoder 551-1 determines that an error is detected from the write data or the read data, then the determination unit 553 determines whether the number of bits of the detected error is equal to a predetermined number of bits, and outputs the control signal CS to the second ECC corrector 555-1 and the third selector 557, based on the result of the determination. For example, when 72-bit data (including parity bits) is input to the ECC block 500 from the memory controller 100, the predetermined number of bits of the detected error may be 1 bit, although other numbers of bits may be incorporated without departing from the scope of the present teachings.

When the determination unit 553 determines that the number of bits of the detected error is equal to the predetermined number of bits, then the second ECC corrector 555-1 generates ECC data by performing ECC on the write data or the read data received from the second ECC decoder 551-1, based on the ECC algorithm corresponding to the memory controller 100.

The third selector 557 outputs the ECC data generated by the second ECC corrector 555-1, the write data, or the read data, based on the control signal CS received from the determination unit 553. In this case, when no error is detected in the write data or the read data by the second ECC decoder 551-1 or when the number of bits of the detected error is not equal to the predetermined number of bits, then the third selector 557 outputs the write data or the read data, based on the control signal CS generated by the determination unit 553. In other words, the determination unit 553 selectively controls an output of the third selector 557 based on the determination regarding the write data or the read data.

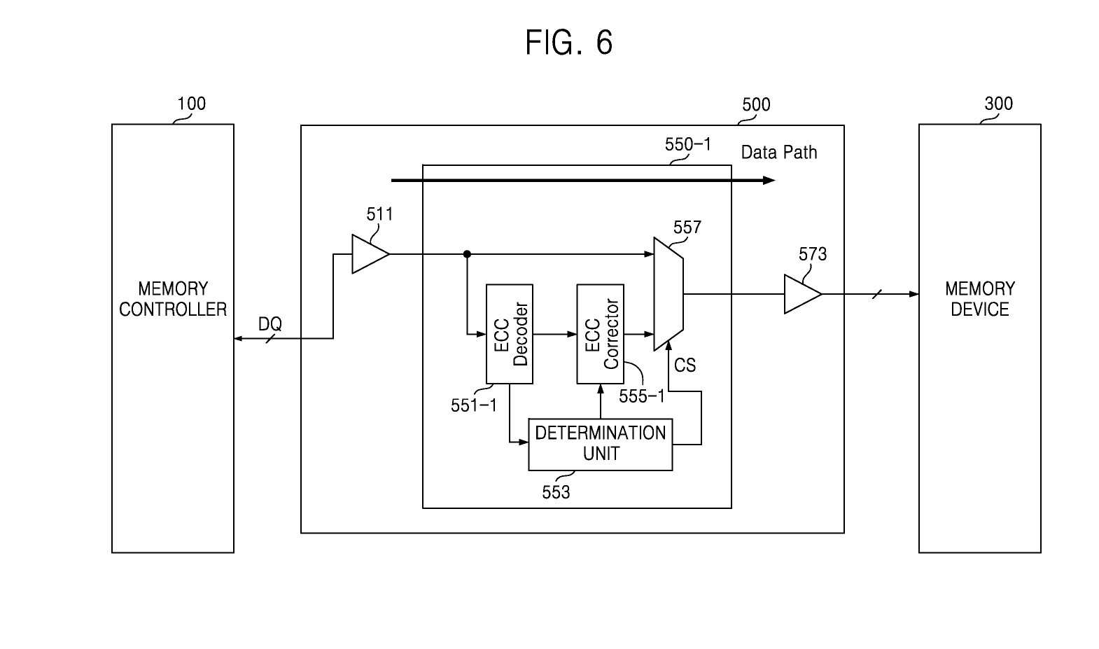

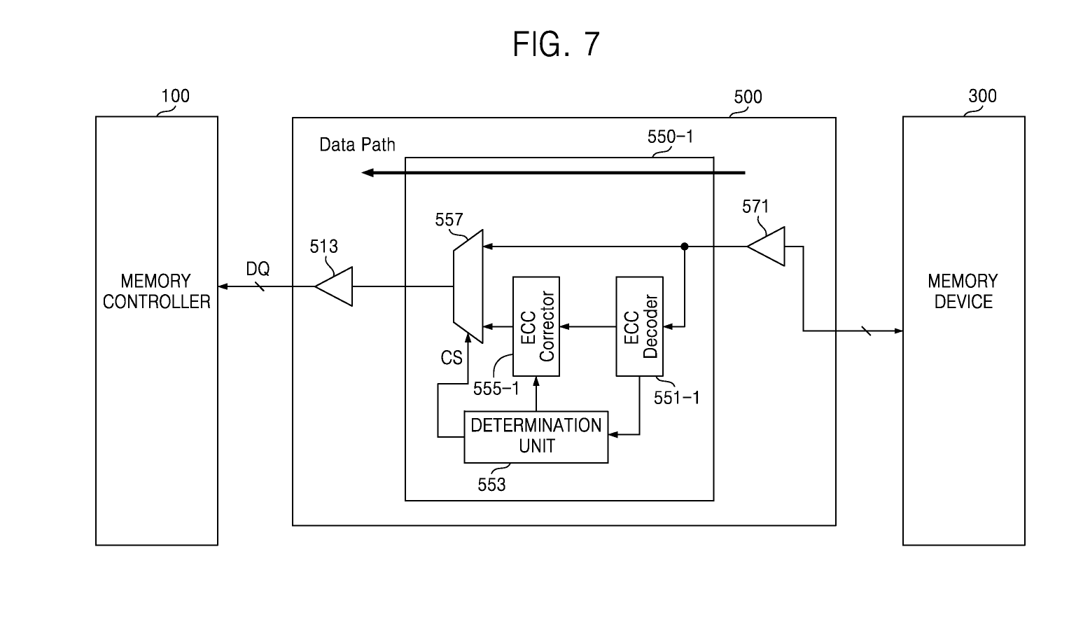

FIG. 6 is a block diagram illustrating a data path corresponding to a write operation of a semiconductor memory device, according to an embodiment of the inventive concept. FIG. 7 is a block diagram illustrating a data path corresponding to a read operation of a semiconductor memory device, according to an embodiment of the inventive concept. FIGS. 6 and 7 illustrate a case in which an ECC algorithm of a memory controller 100 corresponds to a first ECC unit 550-1.

Referring to FIG. 6, the memory controller 100 outputs data to be input to a semiconductor memory device 300 via a data pin DQ, based on a request from the host 10 of FIG. 1. A first buffer gate 511 buffers write data received from the memory controller 100, and outputs the buffered write data to the first ECC unit 550-1.

A second ECC decoder 551-1 determines whether an error is detected in the write data. When it is determined that no error is detected in the write data, then a determination unit 553 outputs a control signal CS indicating this fact to a third selector 557. When it is determined that an error is detected from the write data, then the determination unit 553 determines whether the number of bits of the detected error is equal to a predetermined number of bits and outputs the control signal CS based on the result of the determination. When the determination unit 553 determines that the number of bits of the detected error is equal to the predetermined number of bits, then the second ECC corrector 555-1 generates ECC data for the write data, based on an ECC algorithm corresponding to the first ECC unit 550-1.

The third selector 557 selectively outputs the write data received from the first buffer gate 511 or the ECC data generated by the second ECC corrector 555-1, based on the control signal CS. A fourth buffer gate 573 buffers the write data or the ECC data for the write data received from the third selector 557, and outputs the buffered data to the semiconductor memory device 300.

Referring to FIG. 7, a memory controller 100 reads data from a semiconductor memory device 300 via a data pin DQ, based on a request from the host 10 of FIG. 1. A third buffer gate 571 buffers the read data received from the semiconductor memory device 300 and outputs the buffered read data to a first ECC unit 550-1.

A second ECC decoder 551-1 determines whether an error is detected in the read data. When it is determined that no error is detected in the read data, the determination unit 553 outputs a control signal CS indicating this fact to a third selector 557. When it is determined that an error is detected from the read data, the determination unit 553 determines whether the number of bits of the detected error is equal to a predetermined number of bits and outputs the control signal CS, based on the results of the determination. When the determination unit 553 determines that the number of bits of the detected error is equal to the predetermined number of bits, the second ECC corrector 555-1 may generate ECC data for the read data, based on an ECC algorithm corresponding to the first ECC unit 550-1.

The third selector 557 selectively outputs the read data received from the third buffer gate 571 or the ECC data generated by the second ECC corrector 555-1, based on the control signal CS. A second buffer gate 513 buffers the read data received from the third selector 557 or the ECC data for the read data, and then outputs the buffered read data to the memory controller 100.

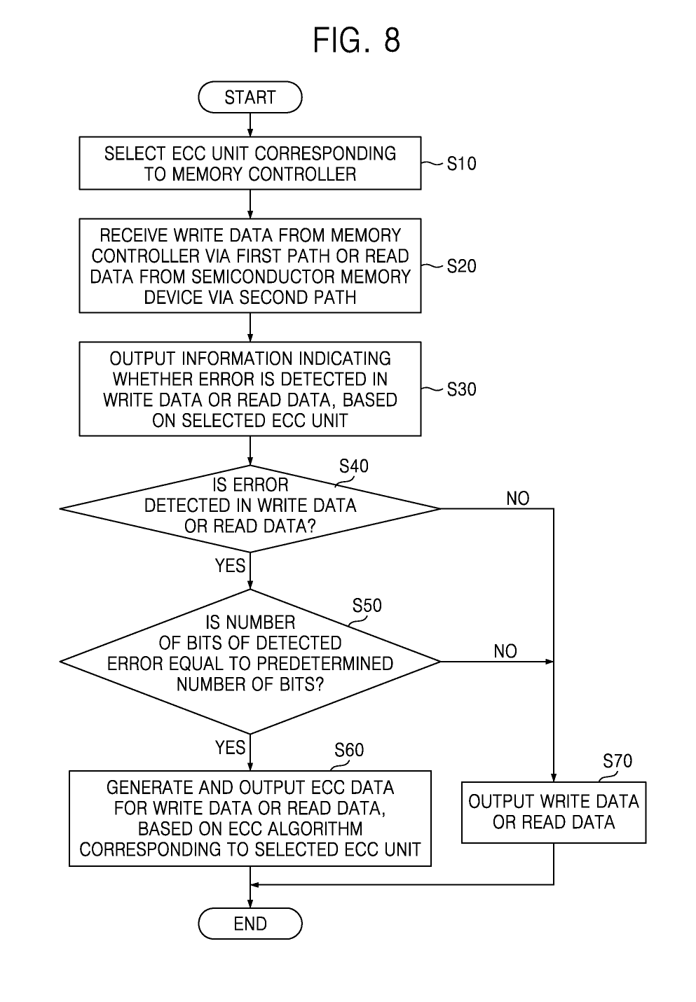

FIG. 8 is a flowchart illustrating a data processing method performed by a memory system, according to an embodiment of the inventive concept. Referring to FIGS. 1 to 8, in operation S10, the ECC logic circuit 530 selects an ECC unit for performing an ECC algorithm corresponding to the memory controller 100 from among ECC algorithms corresponding to the ECC units 550-1 to 550-N. In this case, the ECC unit may be selected when the memory buffer 400 is initialized or when the memory module 200 performs a built-in self test (BIST).

In operation S20, the ECC logic circuit 530 receives write data from the memory controller 100 via a first path or receives read data from the semiconductor memory device 300 via a second path, according to a command CMD received from the memory controller 100.

In operation S30, the ECC decoder 551 of the selected ECC unit corresponding to the memory controller 100 determines whether an error is detected in the received write data or read data, and outputs information indicating the result of the determination. In operation S40, when it is determined that an error has been detected in the write data or the read data, the determination unit 553 then determines whether the number of bits of the detected error is equal to a predetermined number of bits in operation S50.

When it is determined in operation S50 that the number of bits of the detected error is equal to the predetermined number of bits, then the ECC corrector 555 of the selected ECC unit generates ECC data for the write data or the read data, based on the ECC algorithm corresponding to the selected ECC unit, and the selector 557 outputs the generated ECC data, based on a control signal CS generated by the determination unit 553, in operation S60. However, when it is determined in operation S40 that no error is detected from the write data or the read data, or when it is determined in operation S50 that the number of bits of the detected error is not equal to the predetermined number of bits, then the selector 557 outputs the write data or the read data, based on the control signal CS generated by the determination unit 553, in operation S70.

Since the memory buffer 400 includes multiple ECC algorithms corresponding to multiple memory controllers, the memory buffer 400 may detect and correct errors contained in write data received from the memory controller 100 and error contained in read data received from the semiconductor memory device 300. Since the memory controller 100 and the memory buffer 400 may also detect and correct errors, capabilities of detecting and correcting errors contained in data are improved.

According to the above embodiments of the inventive concept, even a memory buffer may detect and correct an error contained in data by using an ECC algorithm corresponding to a memory controller. Thus, capabilities of detecting and correcting an error contained in data are improved. Furthermore, an additional ECC block for a data path is not needed, thus reducing overhead of the system.

While the inventive concept has been described with reference to exemplary embodiments, it will be apparent to those skilled in the art that various changes and modifications may be made without departing from the spirit and scope of the present inventive concept. Therefore, it should be understood that the above embodiments are not limiting, but illustrative.

What is claimed is:

1. A memory system comprising:
a semiconductor memory device;
a memory controller for controlling the semiconductor memory device; and
a memory buffer connected between the semiconductor memory device and the memory controller, the memory buffer being configured to perform error correction coding (ECC) on first data that is received from the memory controller to be stored in the semiconductor memory device and to perform ECC on second data read from the semiconductor memory device.

2. The memory system of claim 1, wherein the memory buffer comprises an ECC block including at least two ECC algorithms, the ECC block being configured to perform ECC according to an ECC algorithm selected from among the at least two ECC algorithms.

3. A semiconductor device comprising:
an error correcting coding (ECC) logic circuit comprising a plurality of different ECC algorithms and an ECC algorithm selector for selecting an ECC algorithm from among the plurality of different ECC algorithms,
wherein the ECC logic circuit is configured to generate ECC data using the ECC algorithm selected by the ECC algorithm selector.

4. The semiconductor device of claim 3, further comprising:
a first selector configured to transmit first data received from outside to the ECC logic circuit and to transmit first ECC data received from the ECC logic circuit to the outside, in response to a command signal; and
a second selector configured to transmit second ECC data received from the ECC logic circuit to a semiconductor memory device and to transmit second data received from the semiconductor memory device to the ECC logic circuit, in response to the command signal,
wherein the ECC logic circuit generates the first ECC data by performing ECC on the second data, and generates the second ECC data by performing ECC on the first data.

5. The semiconductor device of claim 4, wherein the ECC logic circuit further comprises a plurality of ECC units for performing the plurality of different ECC algorithms, respectively, the first ECC data and the second ECC data being respectively generated from the second data and the first data using an ECC unit selected from among the plurality of ECC units.

6. The semiconductor device of claim 5, wherein one of the plurality of ECC units is selected by the ECC algorithm selector when the semiconductor device is initialized or when a built-in self test (BIST) is performed.

7. The semiconductor device of claim 5, wherein each of the plurality of ECC units comprises:
an ECC decoder for determining whether an error is detected from the second data or the first data, based on an ECC algorithm corresponding to the selected ECC unit;
a determination unit for determining whether a number of bits of a detected error is equal to a predetermined number of bits and outputting a control signal based on a result of the determination, when the error is detected from the first data or the second data;
an ECC corrector for generating the first ECC data from the second data or generating the second ECC data from the first data according to the corresponding ECC algorithm, based on the control signal, when the number of bits of the detected error is equal to the predetermined number of bits; and
a third selector for outputting the first ECC data and the second ECC data or outputting the first data and the second data, based on the control signal.

8. The semiconductor device of claim 7, wherein the ECC decoder and the ECC corrector included in each of the plurality of ECC units are embodied according to different logics, based on the corresponding ECC algorithm.

9. The semiconductor device of claim 5, wherein the ECC logic circuit further comprises:
a first selection unit for selecting a path for the received second data and first data, in response to the command signal; and
a second selection unit for selecting a path for the first ECC data and the second ECC data generated by the selected ECC unit, in response to the command signal.

10. The semiconductor device of claim 4, further comprising:
a first buffer unit for buffering the first data received from the outside, outputting the buffered first data to the first selector, buffering the first ECC data received from the first selector, and outputting the buffered first ECC data to the outside; and
a second buffer unit for buffering the second data received from the semiconductor memory device, outputting the buffered second data to the second selector, buffering the second ECC data received from the second selector, and outputting the buffered second ECC data to the semiconductor memory device.

11. The semiconductor device of claim 3, wherein the semiconductor device is a memory buffer is connected between a semiconductor memory device and a memory controller that controls the semiconductor memory device, and is configured to perform ECC on data exchanged between the semiconductor memory device and the memory controller.

12. The semiconductor device of claim 3, wherein the semiconductor device is a memory controller for transmitting the ECC data to a semiconductor memory device, and controlling an operation of the semiconductor memory device.

13. A memory module comprising:
the semiconductor device of claim 3; and
a semiconductor memory device for receiving the ECC data generated by the semiconductor device, and storing the ECC data.

14. The memory module of claim 13, wherein the semiconductor device further comprises:
a first selector configured to transmit first data received from outside to the ECC logic circuit and to transmit first ECC data received from the ECC logic circuit to the outside, in response to a command signal; and
a second selector configured to transmit second ECC data received from the ECC logic circuit to the semiconductor memory device and to transmit second data received from the semiconductor memory device to the ECC logic circuit, in response to the command signal,
wherein the ECC logic circuit generates the first ECC data by performing ECC on the second data, and generates the second ECC data by performing ECC on the first data.

15. A memory system comprising:
the memory module of claim 13; and
a memory controller configured to control operations of the semiconductor memory device installed in the memory module via the semiconductor device.

16. A method of data processing by a memory buffer in a memory system, the method comprising:
selecting an error correcting coding (ECC) unit from among a plurality of ECC units for performing error detection on write data or read data received by the memory buffer and for outputting corresponding ECC information, the plurality of ECC units being configured to perform a corresponding plurality of different ECC algorithms, respectively;
determining whether an error is detected in the received write data or read data based on the ECC information;
outputting the write data or the read data when it is determined that no error is detected; and
generating and outputting ECC data for the write data or the read data, based on the ECC algorithm corresponding to the selected ECC unit, when it is determined that an error is detected.

17. The method of claim 16, further comprising:
when it is determined that the error is detected, determining whether the number of bits of the detected error is equal to a predetermined number of bits;
outputting the write data or the read data when it is determined that the number of bits is not equal to the predetermined number of bits; and
generating and outputting ECC data for the write data or the read data, based on the ECC algorithm corresponding to the selected ECC unit, when it is determined that the number of bits is equal to the predetermined number of bits.

18. The method of claim 16, wherein the ECC algorithm performed by the selected ECC unit corresponds to a memory controller which provides the write data to or receives the read data from the memory buffer.

19. The method of claim 18, wherein selecting the ECC unit occurs when the memory buffer is initialized or when a memory module containing the memory buffer performs a built-in self test (BIST).

20. The method of claim 18, further comprising:
receiving a command signal from the memory controller indicating whether to receive the write data from the memory controller via a first path or to receive the read data from a semiconductor memory device via a second path.
